(19) United States
(12) Patent Application Publication
(10) Pub. No.: US 2006/0038239 A1
(43) Pub. Date: Feb. 23, 2006

(54) Semiconductor device and method of manufacturing the same

(75) Inventors: Yoshinori Tsuchiya, Yokohama-shi (JP); Akira Nishiyama, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/114,105

(22) Filed: Apr. 26, 2005

(30) Foreign Application Priority Data
Aug. 20, 2004 (JP) 2004-240847

(51) Int. Cl. H01L 23/62

(52) U.S. Cl. 257/369

(57) ABSTRACT

Disclosed is a semiconductor device comprising a semiconductor substrate having isolation regions a p-type MIS transistor comprising a pair of source/drain regions formed in the semiconductor substrate, a gate insulating film formed on the semiconductor substrate, and a gate electrode formed on the gate insulating film and having a first metal layer at least at the gate electrode/gate insulator interface, and an n-type MIS transistor comprising a pair of source/drain regions formed in the semiconductor substrate, a gate insulating film formed on the semiconductor substrate, and a gate electrode formed on the gate insulating film and having a boride layer of the first metal at least at an interface thereof with the gate insulating film.

### CROSS-REFERENCE TO RELATED APPLICATIONS

This application is based upon and claims the benefit of priority from prior Japanese Patent Application No. 2004-240847, filed Aug. 20, 2004, the entire contents of which are incorporated herein by reference.

### BACKGROUND OF THE INVENTION

1. Field of the Invention

This invention relates to a semiconductor device, and in particular, to a MIS device constituting a silicon large scale integrated circuit which is capable of realizing advanced information processing.

2. Description of the Related Art

The silicon super integrated circuit is one of basic technologies for supporting the approaching advanced information society. In order to enhance the integrated circuit in function, it is necessary to enhance the performance of a MIS device constituting one of the constituent elements of the integrated circuit. The performance of semiconductor elemental device has been enhanced fundamentally according to the proportional scale-down rule. In recent years however, due to various physical limiting factors, it is now becoming more difficult to further enhance the performance of semiconductor elemental devices through the ultra-micro fabrication of the semiconductor elements and, still more, to enable the semiconductor element devices to operate satisfactorily.

One of the problems involved in this case is a obstruction by the depletion of the polycrystalline Si gate electrode in an attempt to make the electric insulating film thinner. Although the enhancement of performance of an MIS device has been achieved by thinning the gate insulating film according to the proportional scale-down rule, it is now becoming increasingly difficult to further enhance the performance of an MIS device due to the effect of the polycrystalline Si gate depletion. In an advanced technological generation where the thickness of gate oxide film is reduced to less than 1 nm, the depletion layer capacitance of the polycrystalline Si gate electrode would be increased to around 30% of the capacitance of the gate oxide film. It is possible, to cancel the depletion layer capacitance, through the employment of a metal gate electrode in place of the polycrystalline Si gate electrode. Further, it is also desirable to employ a metal gate electrode from the viewpoint of lowering the electrical resistance of the gate electrode.

In the case of a MIS device however, it is required, to employ gate electrodes differing in work function from each other for the purpose of obtaining an optimum threshold voltage value depending on the conductivity type. Therefore, if a metal gate is to be simply employed, two kinds of metallic materials are required to be employed, thus resulting in complication of the manufacturing process as well as in increase in manufacturing cost. Although it has been proposed to employ a technique of introducing impurities into a silicide layer for simplifying the manufacturing process of the metal gate, the range for enabling the control of the work function is so narrow that it is actually impossible to obtain a work function for realizing an optimum threshold voltage in the MIS device. Further, it has been also tried to control the work function through alloying. However, when use of an Ru—Ta alloy is tried, there will be raised problems that the performance of the MIS device is degraded due to the inclusion of Ru and that the apparatus for manufacturing the MIS device is contaminated by these metals.

### BRIEF SUMMARY OF THE INVENTION

A semiconductor device according to one aspect of the present invention comprises a semiconductor substrate having isolation regions; a p-type MIS transistor comprising a pair of source/drain regions formed in the semiconductor substrate, a gate insulating film formed on the semiconductor substrate, and a gate electrode formed on the gate insulating film and having a first metal layer at least at the gate electrode/gate insulating film interface; and an n-type MIS transistor comprising a pair of source/drain regions formed in the semiconductor substrate, a gate insulating film formed on the semiconductor substrate, and a gate electrode formed on the gate insulating film and having a boride layer of the first metal at least at the gate electrode/gate insulating film interface.

A semiconductor device according to another aspect of the present invention comprises a semiconductor substrate having isolation regions; a p-type MIS transistor comprising a pair of source/drain regions formed in the semiconductor substrate, a gate insulating film formed on the semiconductor substrate, and a gate electrode formed on the gate insulating film and having a carbide layer of a first metal at least at the gate electrode/gate insulating film interface; and an n-type MIS transistor comprising a pair of source/drain regions formed in the semiconductor substrate, a gate insulating film formed on the semiconductor substrate, and a gate electrode formed on the gate insulating film and having a boride layer of the first metal at least at the gate electrode/gate insulating film.

A method of manufacturing a semiconductor device according to a further aspect of the present invention comprises forming an insulating film on a semiconductor substrate having a p-type impurity region and an n-type impurity region which are isolated from each other; forming a metal layer on the insulating film; forming a boron source film selectively on the metal layer located in the p-type impurity region; heat-treating the semiconductor substrate having the boron source film to change all the metal layer to metal boride film thereof to selectively form a metal boride film in the p-type impurity region; forming a gate electrode of an n-type MIS transistor in the p-type impurity region by selectively removing the metal boride film; forming a gate electrode of a p-type MIS transistor in the n-type impurity region by selectively removing the metal film; and forming sidewall insulating films on a sidewall of gate electrode of the n-type MIS transistor and a sidewall of gate electrode of the p-type MIS transistor.

A method of manufacturing a semiconductor device according to a further aspect of the present invention comprises forming an insulating film on a semiconductor substrate having a p-type impurity region and an n-type impurity region which are isolated from each other; forming a metal boride layer on the insulating film; forming a boron absorption film selectively on the metal boride film located in the n-type impurity region; heat-treating the semiconductor substrate having the boron absorption film formed thereon to diffuse boron from the metal boride film in the n-type impurity region to selectively form a metal layer contacted with the insulating film; forming a gate electrode of an n-type MIS transistor in the p-type impurity region by selectively removing the metal boride film; forming a gate electrode of a p-type MIS transistor in the n-type impurity region by selectively removing the metal film; and forming sidewall insulating films on a sidewall of gate electrode of the n-type MIS transistor and a sidewall of gate electrode of the p-type MIS transistor.

A method of manufacturing a semiconductor device according to a further aspect of the present invention comprises forming an insulating film on a semiconductor substrate having a p-type impurity region and an n-type impurity region which are isolated from each other; forming a metal layer on the insulating film; ion-implanting boron selectively into the metal layer located in the p-type impurity region to form a metal boride film; forming a gate electrode of an n-type MIS transistor in the p-type impurity region by selectively removing the metal boride film; forming a gate electrode of a p-type MIS transistor in the n-type impurity region by selectively removing the metal film; and forming sidewall insulating films on a sidewall of gate electrode of the n-type MIS transistor and a sidewall of gate electrode of the p-type MIS transistor.

A method of manufacturing a semiconductor device according to a further aspect of the present invention comprises forming an insulating film on a semiconductor substrate having a p-type impurity region and an n-type impurity region which are isolated from each other; selectively forming a boron layer through adsorption of boron on the insulating film which is located in the p-type impurity region; forming a metal layer on the boron film and on the insulating film; heat-treating the semiconductor substrate having the metal layer formed thereon to diffuse boron from the boron film into the metal layer to selectively form a metal boride film in the p-type impurity region, the metal boride film being contacted with the insulating film; forming a gate electrode of an n-type MIS transistor in the p-type impurity region by selectively removing the metal boride film; forming a gate electrode of a p-type MIS transistor in the n-type impurity region by selectively removing the metal film; and forming sidewall insulating films on a sidewall of gate electrode of the n-type MIS transistor and a sidewall of gate electrode of the p-type MIS transistor.

### BRIEF DESCRIPTION OF THE SEVERAL VIEWS OF THE DRAWING

FIG. 1 is a cross-sectional view of a semiconductor device according to one embodiment of the present invention;

FIG. 2 is a cross-sectional view illustrating one step in the method of manufacturing a semiconductor device according to one embodiment of the present invention;

FIG. 3 is a cross-sectional view illustrating the next step following the step shown in FIG. 2;

FIG. 4 is a cross-sectional view illustrating the next step following the step shown in FIG. 3;

FIG. 5 is a cross-sectional view illustrating the next step following the step shown in FIG. 4;

FIG. 6 is a cross-sectional view illustrating a step in the manufacture of a semiconductor device according to another embodiment of the present invention;

FIG. 7 is a cross-sectional view illustrating the next step following the step shown in FIG. 6;

FIG. 8 is a cross-sectional view illustrating the next step following the step shown in FIG. 7;

FIG. 9 is a cross-sectional view illustrating the next step following the step shown in FIG. 8;

FIG. 10 is a cross-sectional view illustrating a step in the manufacture of a semiconductor device according to a further embodiment of the present invention;

FIG. 11 is a cross-sectional view illustrating the next step following the step shown in FIG. 10;

FIG. 12 is a cross-sectional view illustrating the next step following the step shown in FIG. 11;

FIG. 13 is a cross-sectional view illustrating the next step following the step shown in FIG. 12;

FIG. 14 is a cross-sectional view of a semiconductor device according to a further embodiment of the present invention;

FIG. 15 is a cross-sectional view illustrating a step in the method of manufacturing a semiconductor device according to a further embodiment of the present invention;

FIG. 16 is a cross-sectional view illustrating the next step following the step shown in FIG. 15;

FIG. 17 is a cross-sectional view illustrating the next step following the step shown in FIG. 16;

FIG. 18 is a cross-sectional view illustrating the next step following the step shown in FIG. 17;

FIG. 19 is a cross-sectional view of a semiconductor device according to a still further embodiment of the present invention;

FIG. 20 is a cross-sectional view illustrating a step in the method of manufacturing a semiconductor device according to a still further embodiment of the present invention;

FIG. 21 is a cross-sectional view illustrating the next step following the step shown in FIG. 20;

FIG. 22 is a cross-sectional view illustrating the next step following the step shown in FIG. 21;

FIG. 23 is a cross-sectional view illustrating the next step following the step shown in FIG. 22;

FIG. 24 is a cross-sectional view of a semiconductor device according to a still further embodiment of the present invention;

FIG. 25 is a cross-sectional view of a semiconductor device according to a still further embodiment of the present invention;

FIG. 26 is a cross-sectional view of a semiconductor device according to a still further embodiment of the present invention;

FIG. 27 is a graph illustrating the dependency of the work function required in a complete depletion type device on the film thickness of single crystalline silicon layer; and

FIG. 28 is a cross-sectional view of a semiconductor device according to a still further embodiment of the present invention.

### DETAILED DESCRIPTION OF THE INVENTION

Next, embodiments of the present invention will be explained with reference to drawings.

### Embodiment 1

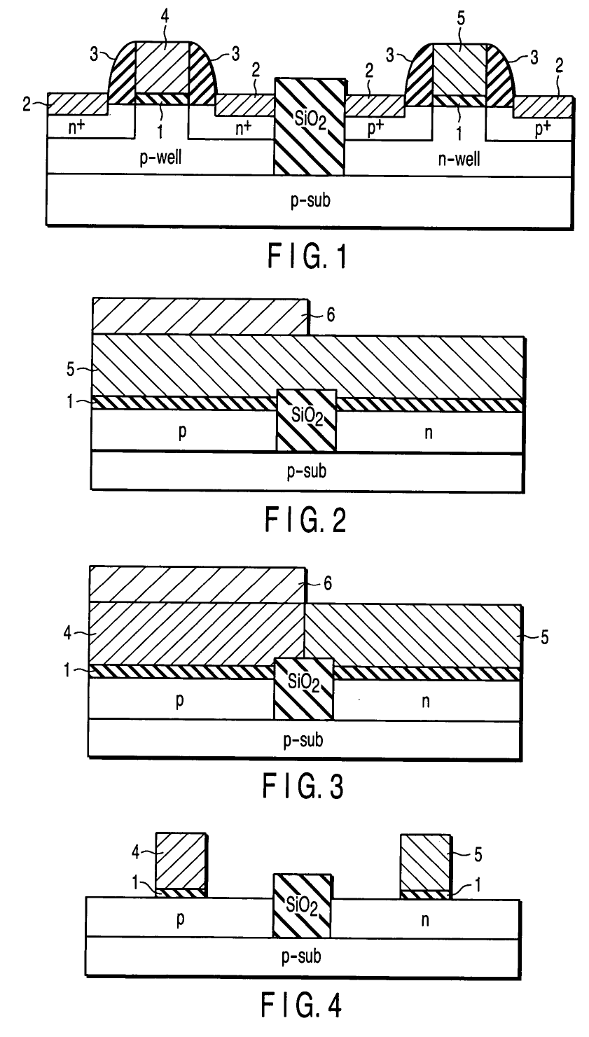

FIG. 1 is a cross-sectional view of a semiconductor device according to this embodiment.

In the semiconductor device shown in FIG. 1, a p-type impurity region (p-type well) and an n-type impurity region (n-type well) are separately formed in a p-type silicon substrate. A gate insulating film 1 is formed of an thermal-grown silicon oxide film in both the n-type and p-type impurity regions. In this case, the film thickness of the gate insulating film 1 should preferably be 2 nm or less. The gate electrode film is formed on the gate insulating film. In an n-type MIS transistor, the gate electrode is constituted by an MoB₂ layer 4. Whereas in a p-type MIS transistor, the gate electrode is constituted by an Mo layer 5. In both of these MIS transistors, the height of the gate electrode should desirably be set to around 50 nm.

In the p-type well, a source region and a drain region, both constituted by a heavily n-type impurity doped region, are formed with the gate insulating film 1 being interposed therebetween. Further, a nickel silicide (NiSi) layer 2 constituting a contact electrode is formed on the source/drain diffusion regions, thereby fabricating the n-type MIS transistor in the p-type well region. On the other hand, in the n-type well region, a source region and a drain region, both constituted by a heavily p-type impurity doped region, are formed with the gate insulating film 1 being interposed therebetween. Further, in the same manner as in the case of the n-type MIS, an NiSi layer 2 is formed on the source/drain diffusion regions, thereby fabricating the p-type MIS transistor in the n-type impurity region.

These n-type MIS transistor and p-type MIS transistor act complementarily to constitute a CMIS device. Although NiSi is employed as a material for the upper contact of the source/drain regions in this embodiment, it is possible to employ, other than NiSi, various silicides which exhibits metallic electric conductivity. For example, it is possible to employ silicides of V, Cr, Mn, Y, Mo, Ru, Rh, Hf, Ta, W, Ir, Co, Ti, Er, Pt, Pd, Zr, Gd, Dy, Ho and Er.

Further, although silicon oxide film is employed herein as the gate insulating film, it is also possible to employ an insulating film exhibiting a higher dielectric constant (a ferroelectric insulating film) than the silicon oxide film. For example, it is possible to employ, as the gate insulating film, Si₃N₄, Al₂O₃, Ta₂O₅, TiO₂, La₂O₅, CeO₂, ZrO₂, HfO₂, SrTiO₃ and Pr₂O₃, for instance. It is also possible to effectively employ a mixed material comprising silicon oxide into which a metallic ion is intermingled such as Zr silicate and Hf silicate. These materials may be combined in any manner. It is simply required to suitably select a material desirable for a transistor of any generation.

As for the materials for the gate electrode, it is required to employ a material which has low resistivity (50 μΩ·cm or less) and has a thermal stability to withstand the source/drain impurity-activating heat treatment (about 1000° C.). As for the work function of the gate electrode material, the same magnitude of value as the value of work function which is now realized in a polycrystalline Si electrode is required. More specifically, in the case of the n-type MIS transistor, the work function in the vicinity of a bottom of Si conduction band is required to be about 4 eV, and in the case of the p-type MIS transistor, the work function in the vicinity of an top of Si valence band is required to be about 5 eV.

MoB₂ and Mo are both excellent in thermal stability, i.e., the melting point being 2100° C. and 2896° C., respectively. The resistivity of MoB₂ and Mo are both very low, i.e., 45 μΩ·cm and 5 μΩ·cm, respectively. Further, with respect to the work function of these materials, 3.9 eV for MOB₂ and 4.9 eV for Mo. Therefore, MOB₂ and Mo are considered both suited for use as a gate electrode material, i.e., they are capable of meeting all of the aforementioned requirements. Mo can be transformed into carbide, i.e., MoC. MoC is excellent in heat resistance, i.e., the melting point being 2695° C., and the work function is 5.2 eV. Accordingly, it is possible to further modulate the work function by using MoC. In the following embodiment, there will be explained about one example where Mo is employed as the gate electrode of p-type MIS transistor. However, similar effects can be also attained even if MoC is employed in place of Mo.

As described below, it is possible, through a suitable combination of these electrode materials, to employ the same transistor-fabricating procedures as those to be employed in the fabrication of the conventional polycrystalline Si electrode without complicating the manufacturing process of the transistor. Therefore, a metal gate electrode can be easily introduced into a CMIS device.

FIGS. 2 to 5 are cross-sectional views illustrating respectively a first manufacturing method of the semiconductor device shown in FIG. 1.

First of all, by ion implantation, a p-type impurity region (p-type well) and an n-type impurity region (n-type well) are formed on a p-type silicon substrate. An element device isolation is formed in advance by a shallow trench method. Then, the surface of the silicon substrate is thermally oxidized to form a silicon thermal-oxide film 1 having a thickness of about 2 nm. Thereafter, a Mo layer 5 is deposited on the entire surface by the sputtering method for example. Alternatively, this deposition of the Mo layer 5 may be performed by the CVD method using a raw gas such as Mo(C₅H₅)₂H₂ or Mo(CH₃C₅H₅)₂H₂. A CrB₂ layer is then deposited on this Mo layer 5 by the sputtering method for example. Subsequently, the CrB₂ layer is worked by using lithography to form a pattern, thereby selectively leaving a CrB₂ layer 6 in an n-type MIS transistor-forming region (p-well region) as shown in FIG. 2.

The heat of formation of MoB₂ is −123 kJ/mol and hence larger negatively than the heat of formation of CrB₂ (−94.2 kJ/mol) and therefore, MoB₂ is more stable as compared with CrB₂. Accordingly, when the CrB₂ layer 6 is heat-treated at a temperature of 900° C. or so, the boron (B) in the CrB₂ layer 6 diffuses into the Mo layer 5, thereby selectively forming an MOB₂ layer 4 as shown in FIG. 3. With regard to the temperature of this heat treatment, the optimum condition may differ depending on the thickness of the Mo layer. It is known that the solid phase reaction and solid phase diffusion at an interface between solid bodies generally initiate at a temperature (° C.) of about ⅓ of the melting point of the solid material. Therefore, the condition for the heat treatment can be determined in such a way that the temperature should be not lower than that enabling the solid phase reaction or solid phase diffusion to take place, a specific optimum condition being selected depending on the thickness of the Mo layer. The CrB₂ layer 6 acts as a boron source film for feeding boron to the underlying Mo layer 5. It is required in this case that boron sufficiently diffuses into the Mo layer 5 to form the MoB₂ layer 4 contacted with the silicon thermal-oxide film. It should be noted that, other than CrB₂, it is also possible to employ, as a boron source film, any metal boride whose absolute value of heat of formation is lower than that of MoB₂. For example, it is possible to employ MnB₂, CoB, AlB₂, FeB, MgB₂ and NiB.

The MoB₂ layer 4 formed in the p-type well region in this manner is worked together with the underlying silicon thermal-oxide film 1 by anisotropic etching. The Mo layer 5 in the n-type well region is also worked in the same manner as described above to form a gate portion as shown in FIG. 4. By using the gate portion as a mask, arsenic and boron are respectively injected by ion implantation into the semiconductor substrate to create heavily impurity doped regions for the source/drain regions of n-type and p-type MIS transistors.

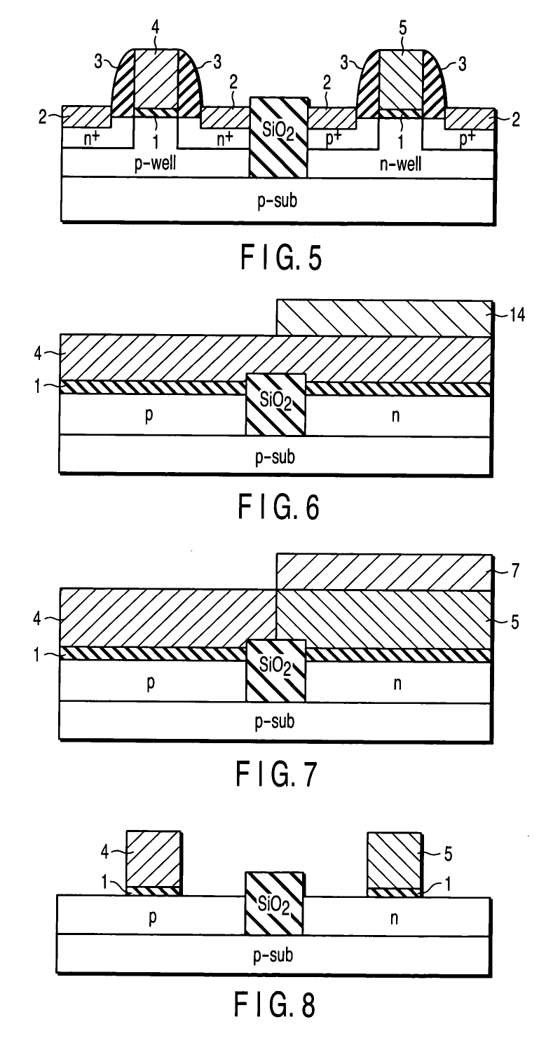

In order to establish insulation between the gate electrode and the source/drain regions, an insulating sidewall 3 is formed on each of the sidewalls of the gate portion. Thereafter, by sputtering deposition, a Ni film (20 nm in thickness) is formed on the entire surface and then heat-treated at a temperature of 400° C. Then, unreacted portions of Ni are selectively removed to form the NiSi contact electrodes 2 in a self-aligned manner, only on the source/drain regions, thus obtaining the structure as shown in FIG. 5.

MoB₂ and Mo are both excellent in high-temperature stability so that they are capable of withstanding a source/drain-activating heat treatment. When a metal gate electrode is to be employed, it is generally considered indispensable, because of the heat resistance of the metal gate electrode, to employ replacement or damascene process, thus concomitantly necessitating the formation of dummy gate or a step of CMP. According to this embodiment however, since MoB₂ and Mo are both excellent in heat resistance, it is possible to fabricate a transistor according to the same sequence of process as in the case where a polycrystalline Si gate electrode is employed. Namely, by the conventional procedures where a gate electrode is formed and worked in advance and then source/drain diffusion regions are formed, the metal gate can be created. As a result, it is now possible to prevent the complication of steps or rise in manufacturing cost. Furthermore, it is also possible to obviate the problems of the prior art that the channel region and gate insulating film of transistor re-expose at the uppermost surface in the replacement or damascene process. Accordingly, it is now possible to concurrently prevent the degrading in performance as well as reliability of the device itself that may occur when the replacement or damascene process is employed.

Incidentally, if MoC is to be employed as a gate electrode of p-type MIS transistor, it is only required to modify the aforementioned process as explained below. Specifically, under the condition where the CrB₂ layer is formed only on the p-type well region as shown in FIG. 3, carbon (C) is injected by ion implantation. As a result, the CrB₂ layer acts as a cap layer in the p-type well region, thereby making it possible to selectively introduce carbon into only Mo of the n-type well region. Thereafter, in the step of activating the impurity of the source/drain regions, carbon sufficiently diffuses down to the interface of SiO₂ of the gate insulating film, thus making it possible to concurrently form the MoC electrode. If the quantity injected of carbon is 1×16 atoms·cm⁻² or more, it would be possible to realize the aforementioned sufficient diffusion of carbon. As an alternative method, by photolithography prior to the deposition of Mo, carbon selectively adsorbs or deposits on the SiO₂ layer only in the n-type well region up to a thickness of about 5 nm. Subsequently, by repeating the aforementioned process, MoC can be formed at the interface of the gate electrode/the gate insulating film of the n-type well region. Since there are a large number of steps to be supplemented in this case, it is more preferable to employ a method employing the ion implantation of carbon. By using these processes, it is possible to form a p-type MIS transistor having a gate electrode constituted by MoC.

FIGS. 6 to 9 illustrate a second manufacturing method of the semiconductor device shown in FIG. 1.

First of all, by ion implantation, a p-type impurity region (p-type well) and an n-type impurity region (n-type well) are formed on a p-type silicon substrate. An element device isolation is formed in advance by a shallow trench method. Then, the surface of the silicon substrate is thermally oxidized to form a silicon thermal-oxide film 1 having a thickness of about 2 nm. Thereafter, a MoB₂ layer 4 is deposited on the entire surface by the sputtering method for example. A Zr layer 14 is then deposited on this MoB₂ layer 4 by the sputtering method for example. Subsequently, the Zr layer 14 is subjected to patterning by using lithography, thereby selectively leaving the Zr layer 14 in a p-type MIS transistor-forming region (n-well region) as shown in FIG. 6.

The heat of formation of ZrB₂ is −300 kJ/mol and hence larger negatively than the heat of formation of MoB₂ (−123 kJ/mol) and therefore, ZrB₂ is more stable as compared with MoB₂. Accordingly, when the MoB₂ layer is heat-treated at a temperature of 900° C. or so, the boron (B) in the MoB₂ layer 4 diffuses into the Zr layer 14, thereby forming an ZrB₂ layer 7 as shown in FIG. 7. The Zr layer 14 acts as a boron absorption film for absorbing boron from the underlying MoB₂ layer 4. As a result, the MoB₂ layer 4 in the p-type MIS transistor-forming region is transformed into an Mo layer 5. It is required in this case that boron sufficiently diffuses into the Zr layer 14 to form the Mo layer 5 contacted with the silicon oxide film 1. With regard to the condition for the heat treatment on this occasion, it can be determined, as in the case of diffusing boron from CrB₂ in the aforementioned first manufacturing method, in such a manner that the temperature should be around ⅓ of the melting point of the material of the layer, a specific optimum condition being selected depending on the thickness of the MoB₂ layer 4 and of the Zr layer 14. Incidentally, it is also possible to deposit different boron absorption films, other than ZrB₂, by suitably selecting a metal so as to make it possible to form any metal boride which is larger in absolute value of heat of formation than that of MoB₂. For example, it is possible to employ, as such a metal, Hf, Ti, Ta, Nd and Ce.

Subsequently, the ZrB₂ layer 7 is removed by etching to expose the Mo layer 5 in the n-type well region.

The Mo layer 5 formed in the n-type well region in this manner is worked together with the underlying silicon thermal-oxide film 1 as gate stack structure by anisotropic etching. The MoB₂ layer 4 in the p-type well region is also worked in the same manner as described above to form a gate portion as shown in FIG. 8. By using this gate portion as a mask, arsenic and boron are respectively injected by ion implantation into the semiconductor substrate to create heavily impurity doped regions for the source/drain regions of n-type and p-type MIS transistors.

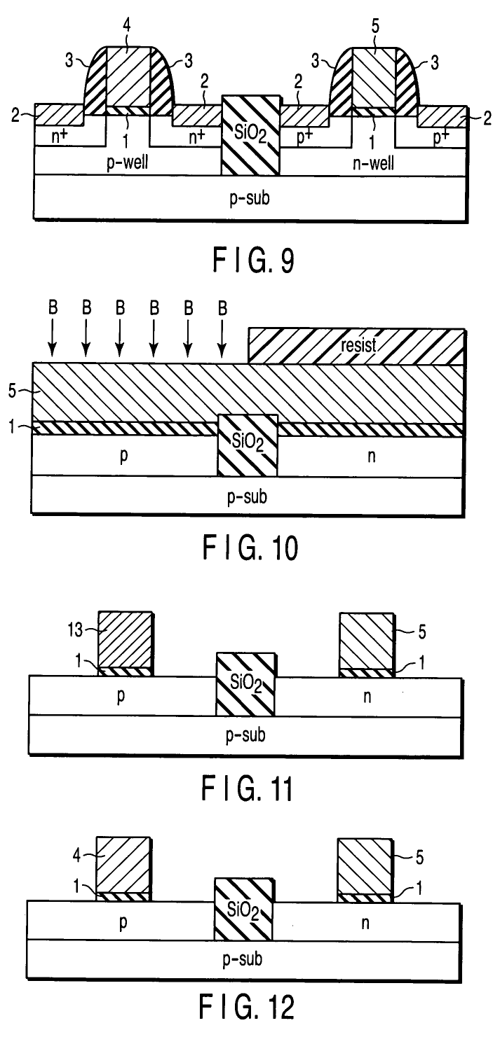

In order to establish insulation between the gate electrode and the source/drain regions, an insulating sidewall 3 is formed on each of the sidewalls of the gate portion. Thereafter, by sputtering deposition, a Ni film (20 nm in thickness) is formed on the entire surface and then heat-treated at a temperature of 400° C. Then, unreacted portions of Ni are selectively removed to form the NiSi contact electrodes 2 in a self-aligned manner, only on the source/drain regions, thus obtaining the structure as shown in FIG. 9. As in the case of the aforementioned first manufacturing process, it is also possible in this case to suppress any increase in manufacturing cost and to enhance the performance and reliability of the device.

Incidentally, if MoC is to be employed as a gate electrode of p-type MIS transistor, it is only required to modify the aforementioned process as explained below. Specifically, by photolithography prior to the deposition of the MoB₂ layer 4, carbon selectively adsorbs or deposits on the SiO₂ layer only in the n-type well region up to a thickness of about 5 nm. Subsequently, by repeating the aforementioned process, MoC can be formed at the interface of the gate electrode/the gate insulating film of the n-type well region. Alternatively, subsequent to the step shown in FIG. 9, under the condition where only the n-type well region is exposed, carbon is injected therein. By supplementing this step, MoC can be concurrently formed in a subsequent impurity-activating step of the source/drain regions. If the quantity injected of carbon is 1×16 atoms·cm⁻² or more, it would be possible to realize the formation of MoC. By using these processes, it is possible to form a p-type MIS transistor having a gate electrode constituted by MoC.

FIGS. 10 to 13 illustrate a third manufacturing method of the semiconductor device shown in FIG. 1.

First of all, by ion implantation, a p-type impurity region (p-type well) and an n-type impurity region (n-type well) are formed on a p-type silicon substrate. An element device isolation is formed in advance by a shallow trench method. Then, the surface of the silicon substrate is thermally oxidized to form a silicon thermal-oxide film 1 having a thickness of about 2 nm. Thereafter, an Mo layer 5 is deposited on the entire surface by the sputtering method for example. A resist film is then deposited on this Mo layer 5 by the sputtering method for example. Subsequently, the resist film is subjected to patterning by using lithography, thereby selectively masking a p-type MIS transistor-forming region (n-well region). Then, as shown in FIG. 10, the ion implantation of boron is selectively performed in an n-type MIS transistor-forming region (p-well region) where the Mo layer 5 is exposed. It is required to inject a high concentration of boron into the Mo layer 5 of the p-well region so as to enable an MoB₂ film to be formed in contact with the silicon thermal-oxide film 1 in a subsequent step. If the quantity injected of boron is 1×16 atoms·cm⁻² or more, it would be possible to realize the formation of MoB₂. The resist film that has been employed as a mask for the n-well region can be easily removed after the ion implantation by using a resist-releasing liquid.

As a result, a Mo layer 13 having a high concentration of boron injected therein is formed in the p-well region. Subsequently, the Mo layer 13 is worked together with the underlying silicon thermal-oxide film 1 by anisotropic etching. The Mo layer 5 in the n-well region is also worked in the same manner as described above to form a gate portion as shown in FIG. 11. By using the gate portion as a mask, arsenic and boron are respectively injected by ion implantation into the semiconductor substrate and then subjected to heat treatment to create heavily impurity doped regions for the source/drain regions of n-type and p-type MIS transistors.

On this occasion, the boron injected into the Mo layer 13 reacts with Mo, thereby turning the Mo layer 13 of n-type MIS transistor into an MoB₂ layer 4 as shown in FIG. 12.

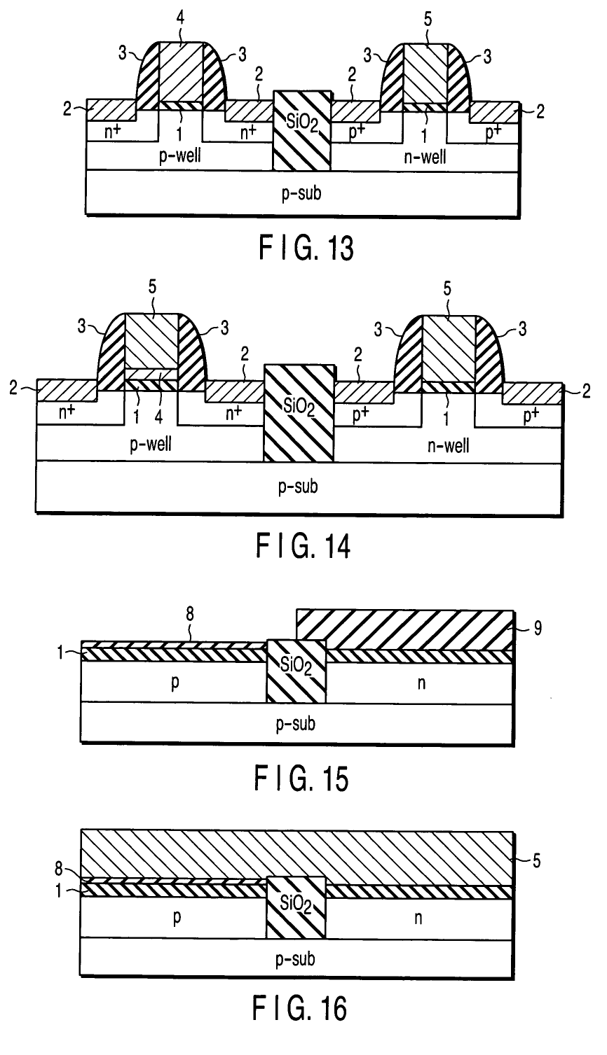

In order to establish insulation between the gate electrode and the source/drain regions, an insulating sidewall 3 is formed on each of the sidewalls of the gate portion. Thereafter, by sputtering deposition, an Ni film (20 nm in thickness) is formed on the entire surface and then heat-treated at a temperature of 400° C. Then, unreacted portions of Ni are selectively removed to form the NiSi contact electrodes 2 in a self-aligned manner, only on the source drain regions, thus obtaining the structure as shown in FIG. 13. Thus, it is possible to obtain the same effects as those obtainable in the manufacturing process already explained above. Moreover, it is possible to dispense with the etching process for removing the CrB₂ film or the ZrB₂ film which is required in the cases of the aforementioned first and second processes, thereby making it possible to further simplify the manufacturing steps, thus saving the manufacturing cost.

Incidentally, if MoC is to be employed as a gate electrode of p-type MIS transistor, it is only required to modify the aforementioned process as explained below. Specifically, immediately before or after the step of injecting boron shown in FIG. 10, an additional step is supplemented wherein the p-type well region is masked by using a resist film and carbon is injected into Mo selectively, i.e., only in the n-type well region, by ion implantation. Due to the addition of this step, it is possible to form MoC in the gate electrode of the p-type MIS transistor when heat treatment for activating the impurity of heavily impurity doped region of the source/drain regions. If the quantity injected of carbon is 1×16 atoms cm⁻² or more, it would be possible to realize the aforementioned formation of MoC. As an alternative method, carbon about 5 nm in thickness may selectively adsorbed only in the n-type well region prior to the deposition of Mo, the carbon diffusing in a subsequent heat treatment, thereby enabling MoC to be formed only in the electrode/SiO₂ interface.

### Embodiment 2

FIG. 14 is a cross-sectional view of a semiconductor device according to this embodiment.

In this embodiment, a p-type impurity region (p-type well) and an n-type impurity region (n-type well) are separately formed in a p-type silicon substrate. Gate insulating films are both formed of an ordinary silicon thermal oxide film 1, the thickness of the silicon thermal oxide film 1 being preferably 2 nm or less. The gate insulating film 1 is provided thereon with a gate electrode. In an n-type MIS transistor, the gate electrode is constituted by a laminate structure comprising an MoB₂ layer 4 and a Mo layer 5. Whereas in a p-type MIS transistor, the gate electrode is constituted by an Mo layer 5. In both of these MIS transistors, the height of the gate electrode should desirably be around 50 nm.

In the p-type well, a source region and a drain region, both constituted by an heavily doped n-type impurity region, are formed with the gate insulating film 1 being interposed therebetween. Further, a nickel silicide (NiSi) layer 2 constituting a contact electrode is formed on the source/drain diffusion regions, thereby fabricating the n-type MIS transistor in the p-type well region. On the other hand, in the n-type well region, a source region and a drain region, both constituted by a p-type high concentration impurity region, are formed with the gate insulating film 1 being interposed therebetween. Further, in the same manner as in the case of the n-type MIS transistor, an NiSi layer 2 is formed on the source/drain diffusion regions, thereby fabricating the p-type MIS transistor in the n-type impurity region. These n-type MIS transistor and p-type MIS transistor act complementarily to constitute a CMIS device.

FIGS. 15 to 18 illustrate the manufacturing method of the semiconductor device shown in FIG. 14.

First of all, by ion implantation, a p-type impurity region (p-type well) and an n-type impurity region (n-type well) are formed on a p-type silicon substrate. An element device isolation is formed in advance by a shallow trench method. Then, the surface of the silicon substrate is thermally oxidized to form a silicon thermal-oxide film 1 having a thickness of about 2 nm. Thereafter, the p-type MIS transistor region is selectively capped with an Si₃N₄ layer 9. Then, by using plasma of B₂H₆ gas, boron is adsorbed on the surface of the silicon thermal-oxide film 1 of the n-type MIS transistor region to selectively form a boron layer 8 as shown in FIG. 15.

The Si₃N₄ layer 9 employed for capping the p-type MIS transistor region is then removed and a Mo layer 5 is deposited on the entire surface as shown in FIG. 16. This deposition of the Mo layer 5 may be performed by the sputtering method or CVD method for instance.

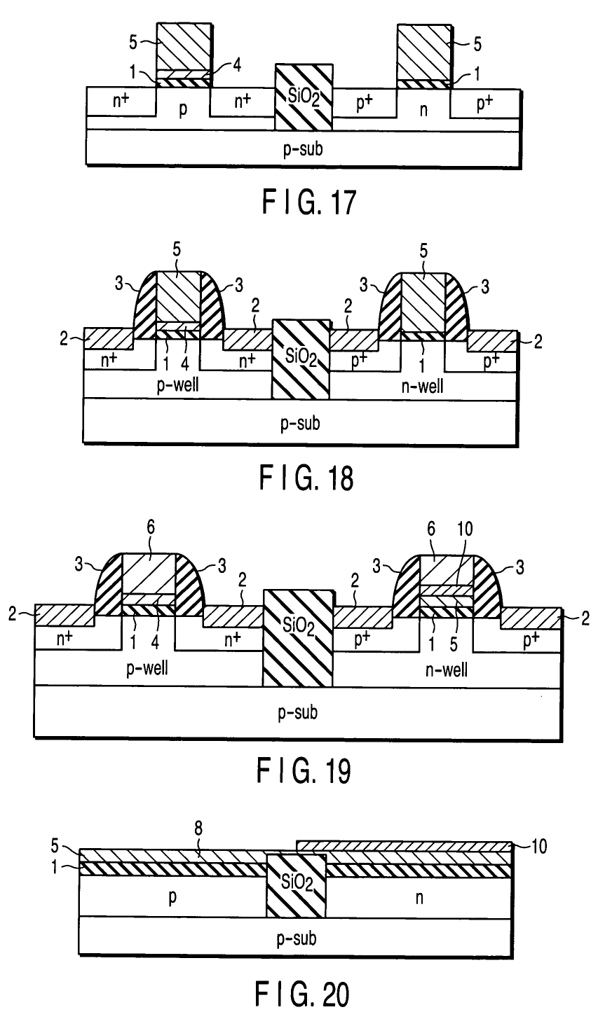

Subsequently, the Mo layer is patterned by using lithography and anisotropic etching to form the gate electrodes. Arsenic and boron are respectively injected by ion implantation into the semiconductor substrate to create heavily impurity doped regions for the source/drain regions of n-type and p-type MIS transistors. In the heat treatment for activating impurity at this step, a reaction between Mo and boron occurs at the interface between the Mo layer 5 and the gate insulating film, thereby creating an MoB₂ layer 4 at the interface of the gate insulating film in the n-type MIS transistor region as shown in FIG. 17.

In order to establish insulation between the gate electrode and the source/drain regions, an insulating sidewall 3 is formed on each of the sidewalls of the gate portion. Thereafter, by sputtering deposition, an Ni film (20 nm in thickness) is formed on the entire surface and then heat-treated at a temperature of 400° C. Then, unreacted portions of Ni are selectively removed to form the NiSi contact electrodes 2 in a self-aligned manner, only on the source/drain regions, thus obtaining the structure as shown in FIG. 18.

In the aforementioned manufacturing process, the film thickness of the MOB₂ layer 4 to be formed in the n-type MIS transistor region is not more than 2-3 nm. Only the work function value of at the gate electrode/gate insulator film interface effects a silicon channel region through an insulating film. Accordingly, a material that determines the work function is only required to exist at least at the interface of the gate electrode with the gate insulating film. The work function of the gate electrode in this embodiment is determined by the work function of MoB₂ in the n-type MIS transistor and by the work function of Mo in the p-type MIS transistor. Further, irrespective of the conductivity type, all of these gate electrodes are almost entirely constituted by Mo. As a result, the gate electrode of the n-type MIS transistor can be made lower resistivity, thereby making it possible to realize high-speed operation of the device. Further, the gate electrodes are formed of a single material in the both conductive type of transistor except the interface of the gate insulating film, the etching can be easily performed when working the gate portions, thereby making it possible to simplify the manufacturing process.

Incidentally, if MoC is to be employed as a gate electrode of p-type MIS transistor, it is only required to modify the aforementioned process as explained below. Specifically, subsequent to the step shown in FIG. 16, an additional step is supplemented wherein the p-type well region is masked by using a resist film and carbon is injected into Mo selectively, i.e., only in the n-type well region, by ion implantation. Due to the addition of this step, it is possible to form MoC in the gate electrode of the p-type MIS transistor when heat treatment for activating the impurity of the heavily impurity doped region of the source/drain regions. As an alternative method, a resist mask may be employed in place of the Si₃N₄ mask employed at the step shown in FIG. 15. Subsequently, this resist mask is removed by using a releasing liquid or by dry etching. The surface of the SiO₂ film which is exposed as a result of the removal of the resist mask is now in a state where carbon included in the resist is adsorbed thereon as a residual carbon. Then, Mo is deposited on this SiO₂ surface and subsequently subjected to a heating step, thereby making it possible to form MoC at the interface of the electrode/SiO₂ locating only in the n-type well region. It is possible, in this manner, to fabricate a p-type MIS transistor having a gate electrode consisting of MoC.

### Embodiment 3

FIG. 19 is a cross-sectional view of a semiconductor device according to this embodiment.

In this embodiment, a p-type impurity region (p-type well) and an n-type impurity region (n-type well) are separately formed in a p-type silicon substrate. Gate insulating films are both formed of an ordinary silicon thermal oxide film 1, the thickness of the silicon thermal oxide film 1 being preferably 2 nm or less. A gate electrode is formed on the gate insulating film. In an n-type MIS transistor, the gate electrode is constituted by a laminate structure comprising an MoB₂ layer 4 and a CrB₂ layer 6. Whereas in a p-type MIS transistor, the gate electrode is constituted by a laminate structure comprising an Mo layer 5, a TaSiN layer 10 and a CrB₂ layer 6. In both of these MIS transistors, the height of the gate electrode should desirably be around 50 nm and the thickness of the TaSiN layer 10 should preferably be 5 nm or less in order to minimize differences in height among these electrodes.

In the p-type well, a source region and a drain region, both constituted by a heavily n-type impurity doped region, are formed with the gate insulating film 1 being interposed therebetween. Further, a nickel silicide (NiSi) layer 2 constituting a contact electrode is formed on the source/drain diffusion regions, thereby fabricating the n-type MIS transistor in the p-type well region. On the other hand, in the n-type well region, a source region and a drain region, both constituted by a heavily p-type impurity doped region, are formed with the gate insulating film being interposed therebetween. Further, in the same manner as in the case of the n-type MIS transistor, an NiSi layer 2 is formed on the source/drain diffusion regions, thereby fabricating the p-type MIS transistor in the n-type impurity region.

These n-type MIS transistor and p-type MIS transistor act complementarily to constitute a CMIS device. In this embodiment, the TaSiN layer 10 in the gate electrode of the p-type MIS transistor acts as a barrier layer, thereby obstructing the diffusion of boron from the CrB₂ layer 6 into the Mo layer 5. This barrier layer can be formed by using TaN, TiN or TiSiN other than TaSiN.

FIGS. 20 to 23 illustrate one example of manufacturing method of the semiconductor device shown in FIG. 19.

First of all, by ion implantation, a p-type impurity region (p-type well) and an n-type impurity region (n-type well) are formed on a p-type silicon substrate. An element device isolation is formed in advance by a shallow trench method. Then, the surface of the silicon substrate is thermally oxidized to form a silicon thermal-oxide film 1 having a thickness of about 2 nm. Thereafter, an Mo layer 5 and a TaSiN layer 10 are deposited successively on the entire surface to form a laminate layer. These layers can be formed by the sputtering method or the CVD method, the film thickness of each of these layers being set to about 3 nm. Subsequently, the laminate layer is subjected to patterning process by lithography to selectively remove the TaSiN layer 10 in the n-type MIS device region, thus partially leaving the TaSiN layer 10 in the p-type MIS device region as shown in FIG. 20.

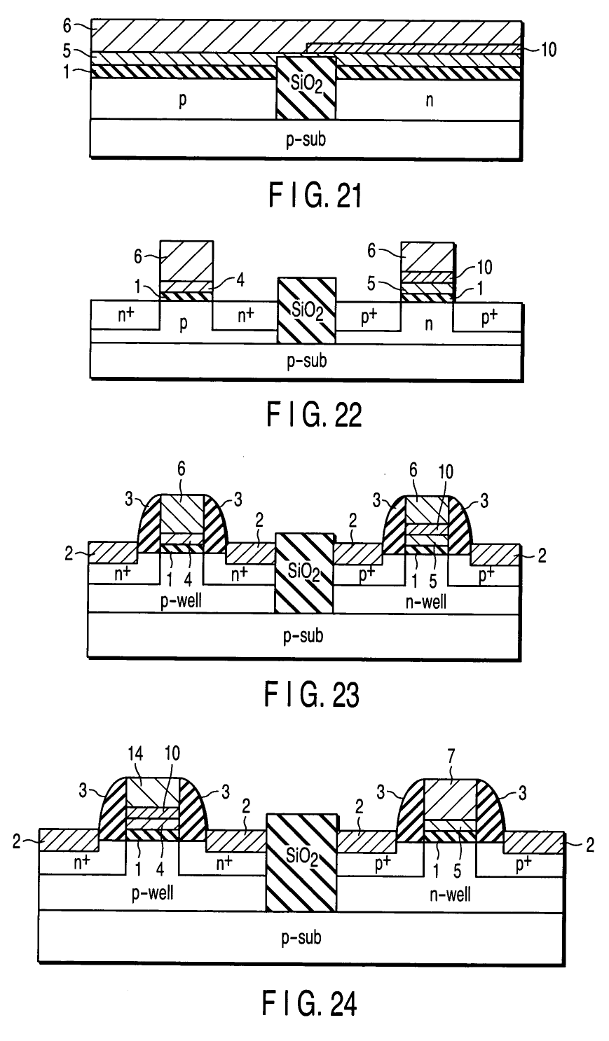

Then, as shown in FIG. 21, a CrB₂ layer 6 having a thickness of about 45 nm is deposited on the entire surface by the sputtering and the working of the gate portion is performed by anisotropic etching. Arsenic and boron are respectively injected by ion implantation into the semiconductor substrate to create heavily impurity doped regions for the source/drain regions of n-type and p-type MIS transistors. In the step of heat treatment for activating impurity, boron diffuses from the CrB₂ layer 6 into the Mo layer 5 in the gate electrode of the n-type MIS device-forming region, thereby creating an MoB₂ layer 4 as shown in FIG. 22. On the other hand, in the p-type MIS transistor region, since the TaSiN layer 10 acts as a barrier layer, the Mo layer 5 can be retained as it is at a region in the vicinity of the interface of gate insulating film 1.

In order to establish insulation between the gate electrode and the source/drain regions, an insulating sidewall 3 is formed on each of the sidewalls of the gate portion. Thereafter, by sputtering deposition, an Ni film (20 nm in thickness) is formed on the entire surface and then heat-treated at a temperature of 400° C. Then, unreacted portions of Ni are selectively removed to form the NiSi contact electrodes 2 in a self-aligned manner, only on the source/drain regions, thus obtaining the structure as shown in FIG. 23.

In this embodiment, almost all portions of the gate electrode are constituted by CrB₂. Since specific resistance of this CrB₂ is about a half (CrB₂:21 μΩ·cm) as compared with MoB₂, the gate electrode of the n-type MIS transistor can be made lower in electrical resistance as compared with the aforementioned Embodiment 1, thus making it possible to further enhance the operation speed of the device.

Incidentally, if MoC is to be employed as an interface layer of the gate electrode of the p-type MIS transistor, it is only required to modify the aforementioned process as explained below. Specifically, a step of depositing a carbon film is supplemented immediately before the deposition of the TaSiN layer 10. By doing so, a laminate structure containing a TaSiN layer and a carbon film will be fabricated in place of the TaSiN layer 10 shown in FIG. 20. When a subsequent heat treatment for activating impurity, Mo will be transformed into MoB₂ in the n-type MIS device-forming region and, at the same time, Mo will be transformed into MoC in the p-type MIS device-forming region also. As for the thickness of the carbon film to be deposited in this case, it is only required to be sufficient to transform Mo into MoC, an optimum thickness being suitably selected depending on the thickness of Mo. As a result, it is now possible to fabricate a p-type MIS transistor having a gate electrode provided with an MoC layer.

### Embodiment 4

FIG. 24 is a cross-sectional view of a semiconductor device according to this embodiment.

In this embodiment, a p-type impurity region (p-type well) and an n-type impurity region (n-type well) are separately formed in a p-type silicon substrate. Gate insulating films are both formed of an ordinary silicon thermal oxide film 1, the thickness of the silicon thermal oxide film 1 being preferably 2 nm or less. A gate electrode is formed on the gate insulating film. In an n-type MIS transistor, the gate electrode is constituted by a laminate structure comprising an MoB₂ layer 4, a TaSiN layer 10 and a Zr layer 14. Whereas in a p-type MIS transistor, the gate electrode is constituted by a laminate structure comprising a Mo layer 5 and a ZrB₂ layer 7. In both of these MIS transistors, the height of the gate electrode should desirably be around 50 nm and the thickness of the TaSiN layer 10 should preferably be 5 nm or less in order to minimize differences in height among these electrodes.

In the p-type well, a source region and a drain region, both constituted by an heavily n-type impurity doped region, are formed with the gate insulating film 1 being interposed therebetween. Further, a nickel silicide (NiSi) layer 2 constituting a contact electrode is formed on the source/drain diffusion regions, thereby fabricating the n-type MIS transistor in the p-type well region. On the other hand, in the n-type well region, a source region and a drain region, both constituted by a heavily p-type impurity doped region, are formed with the gate insulating film being interposed therebetween. Further, in the same manner as in the case of the n-type MIS transistor, an NiSi layer is formed on the source/drain diffusion regions, thereby fabricating the p-type MIS transistor in the n-type impurity region.

These n-type MIS transistor and p-type MIS transistor act complementarily to constitute a CMIS device. In the semiconductor device of this embodiment, the TaSiN layer 10 to be used as a mask layer is selectively formed only in the p-type well region and the CrB₂ layer 6 is replaced by a ZrB₂ layer 7. Other procedures involved in the manufacture of the semiconductor device may be the same as shown in the process shown in FIGS. 20 to 23.

In the following embodiments, although there is employed the structure shown in Embodiment 1 as the gate electrodes of the n-type and p-type MIS transistors, it is also possible to employ any of the structures illustrated in Embodiments 2 to 5.

### Embodiment 5

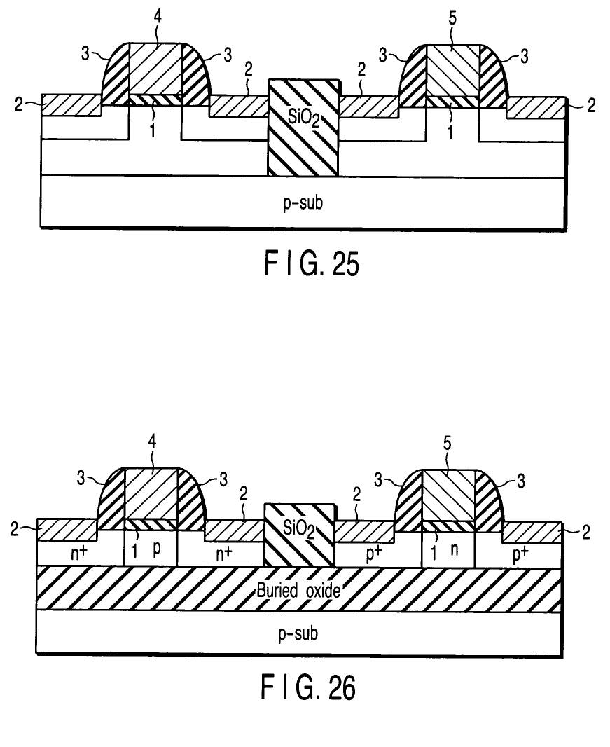

FIG. 25 is a cross-sectional view of a semiconductor device according to this embodiment.

The semiconductor device shown herein is the same in structure as that shown in FIG. 1 except that a silicide laminate structure is employed in place of the heavily impurity doped regions of the source region and the drain region. This structure is so-called Schottky source/drain n-type MOS transistor.

As in the case of the gate electrode portion, it is possible, other than Ni silicide, to employ various metal silicides having a metallic electric conductivity. Especially, since it is required to employ a source/drain electrode material exhibiting a low Schottky barrier to each of conductivity types in the case of Schottky source/drain MIS transistor, it is required to suitably select a combination of two kinds of metal silicides exhibiting a low Schottky barrier to each of the conductivity types, respectively. For example, for the fabrication of the n-type MIS transistor, a rare earth metal silicide such as Er silicide which is relatively low in Schottky barrier to electron can be employed, and for the fabrication of the p-type MIS transistor, a noble metal silicide such as Pt silicide which is relatively low in Schottky barrier to positive hole can be employed. In the following embodiments also, it is possible to employ a metal silicide in place of the heavily impurity doped region in the structure of source/drain regions, thereby fabricating the Schottky source/drain structure.

### Embodiment 6

FIG. 26 is a cross-sectional view of a semiconductor device according to this embodiment.

First of all, by laminating method, an SOI substrate is manufactured, and then, by ion implantation, a p-type impurity region (p-type well) and an n-type impurity region (n-type well) are separately formed in the substrate. As for the concentration of impurity to be injected it should preferably be 1×10¹⁷ atoms·cm⁻³ or less. Further, as for the thickness of the single crystalline silicon layer to be employed as an active region, it should preferably be 5 nm or less. The element device isolation can be formed by local oxidation method or by shallow trench method. The element device isolation may be of mesa type. In this SOI substrate, an n-type MIS transistor and a p-type MIS transistor are formed, thereby constructing a CMIS device.

The structure of the transistor to be formed in this embodiment is the same as in the case of Embodiment 1 shown in FIG. 1. The gate insulating films are both formed of an ordinary silicon thermal oxide film 1 and are provided thereon with a gate electrode, respectively. In the n-type MIS transistor, the gate electrode is formed of an MoB₂ layer 4, and in the p-type MIS transistor, the gate electrode is formed of an Mo layer 5. In this embodiment, the channel portion is entirely depleted, thereby constructing a complete depletion type SOI-CMIS transistor.

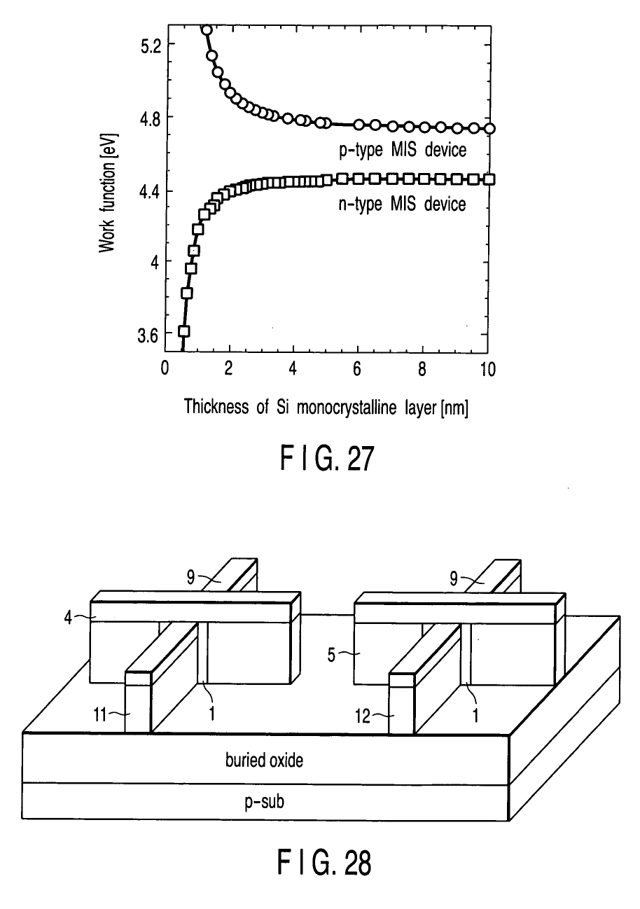

The graph shown in FIG. 27 illustrates the relationship between the film thickness of Si single crystal and the required work function. Herein, the work function is one which is required for obtaining a threshold voltage value of 0.15 eV which is demanded in the generation of 45 nm-thick technology in a complete depletion type SOI-CMIS transistor. When the thickness of the single crystalline silicon layer is decreased to 5 nm or less, electrons of the inversion layer will occupy a high energy level due to quantum effects that will be brought about by the thinning of the single crystalline silicon layer. Therefore, even in the case of the complete depletion type device, it is required to employ a metal gate electrode having the same magnitude of work function as in the case where an n-type/p-type bulk Si substrate is employed.

Accordingly, in a region where an active Si single crystalline layer is as thin as 5 nm or less so as to make quantum effects more prominent, MoB is employed for the gate electrode of the n-type MIS device and Mo is employed for the gate electrode of the p-type MIS device as employed in this embodiment, thereby making it possible to control the work functions of these gate electrodes to a proper threshold voltage value, respectively. More specifically, the thickness of SOI-Si film should preferably be 2 to 3 nm in the case of the p-type MIS transistor and the thickness of the SOI-Si film should preferably be 0.5 to 1 nm in the case of the n-type MIS transistor. Although a laminating method is employed in the manufacture of an SOI structure in this embodiment, it is also possible to employ other methods such as the SIMOX (Separation by Implanted Oxygen) method or epitaxial layer transfer method.

### Embodiment 7

FIG. 28 is a cross-sectional view of a semiconductor device according to this embodiment.

A silicon oxide film is deposited on a p-type silicon substrate. On this silicon oxide film, there is formed a Fin structure constituting the source/drain regions of transistor. Although this Fin structure shown in FIG. 28 is constituted by a laminate structure containing a p-type Si layer 11 and an SiN layer 9 and by a laminate structure containing an n-type Si layer 12 and an SiN layer 9, it is also possible to construct the Fin structure using an Si single layer or insulating layers other than SiN.

Gate electrodes are formed so as to intersect with the Fin structure, and a silicon oxide film 1 is formed as a gate insulating film at the contacting interface between them. This structure is so-called a double-gate MIS transistor where the MIS transistor formed therein has a channel portion at sidewall portions of both of these Fin portions. When a Si single layer is employed at the Fin portion, the top of the Fin will be also turned into a channel region, thus creating a tri-gate MIS transistor.

In the n-type MIS transistor, the gate electrode is formed of an MoB₂ layer 4, and in the p-type MIS transistor, the gate electrode is formed of a Mo layer 5. Although not shown in the drawing, with respect to the source/drain portions, a source region and a drain region, both constituted by an heavily n-type impurity doped region, are formed in the p-type Fin with the gate insulating film 1 being interposed therebetween, and further, a source region and a drain region, both constituted by a heavily p-type impurity doped region, are formed in the n-type Fin with the gate insulating film 1 being interposed therebetween. In the device of three-dimentional structure as set forth in this embodiment, it would be very difficult to make the concentration of impurity uniform in the elevational direction. Therefore, this device may be transformed into a Schottky source/drain structure in the same manner as in the case of Embodiment 5 shown in FIG. 25.

Even when the MIS transistor is constructed in this manner, it will also become a complete depletion type device as in the case of the SOI-MIS transistor of Embodiment 6 shown in FIG. 26. If the thickness of Fin at the channel portion becomes 5 nm or less, it will be required, due to quantum effects, to employ a metal gate electrode having the same work function as in the case where an n-type/p-type bulk Si substrate is employed. Further, since it is very difficult to realize the ion implantation of impurity into a poly-Si electrode in the case of three-dimensional device, the control of threshold voltage value at the MoB and Mo portions would be very effective.

Although a double-gate MIS transistor of Fin structure is employed in this embodiment, it is also possible to employ other three-dimensional devices such as a flat-type double-gate CMIS transistor, a vertical double-gate CMIS transistor, etc.

According to the present invention, it is possible to provide a CMIS device which is low in electrical resistance, free from the depletion of gate, stable in performance at high temperatures, and provided with gate electrodes having a controlled work function. Further, according to the present invention, it is possible to provide a method of manufacturing a CMIS device, which can be executed without accompanying complication of steps.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate having isolation regions;
a p-type MIS transistor comprising a pair of source/drain regions formed in the semiconductor substrate, a gate insulating film formed on the semiconductor substrate, and a gate electrode formed on the gate insulating film and having a first metal layer at least at the gate electrode/gate insulating film interface; and
an n-type MIS transistor comprising a pair of source/drain regions formed in the semiconductor substrate, a gate insulating film formed on the semiconductor substrate, and a gate electrode formed on the gate insulating film and having a boride layer of the first metal at least at the gate electrode/gate insulating film interface.

2. The semiconductor device according to claim 1, wherein the gate electrode in the n-type MIS transistor has the first metal layer formed above on the boride layer of the first metal.

3. The semiconductor device according to claim 1, wherein the first metal is formed of molybdenum.

4. The semiconductor device according to claim 1, wherein the source/drain regions formed in the semiconductor substrate each are formed of a heavily doped impurity region.

5. The semiconductor device according to claim 4, wherein the gate electrode in the p-type MIS transistor and the gate electrode in the n-type MIS transistor are both provided with chromium boride layer on the top surface.

6. The semiconductor device according to claim 5, wherein the gate electrode in the p-type MIS transistor further comprises, between the first metal layer and the chromium boride layer, a barrier layer formed of a material selected from the group consisting of TaSiN, TaN, TiN and TiSiN.

7. A semiconductor device comprising:
a semiconductor substrate having isolation regions;
a p-type MIS transistor comprising a pair of source/drain regions formed in the semiconductor substrate, a gate insulating film formed on the semiconductor substrate, and a gate electrode formed on the gate insulating film and having a carbide layer of a first metal at least at the gate electrode/gate insulating film interface; and
an n-type MIS transistor comprising a pair of source/drain regions formed in the semiconductor substrate, a gate insulating film formed on the semiconductor substrate, and a gate electrode formed on the gate insulating film and having a boride layer of the first metal at least at the gate electrode/gate insulating film.

8. The semiconductor device according to claim 7, wherein the gate electrode in the n-type MIS transistor has the first metal layer formed on the boride layer of the first metal.

9. The semiconductor device according to claim 7, wherein the first metal is formed of molybdenum.

10. The semiconductor device according to claim 7, wherein the source/drain regions formed in the semiconductor substrate each are formed of a heavily doped impurity region.

11. The semiconductor device according to claim 10, wherein the gate electrode in the p-type MIS transistor and the gate electrode in the n-type MIS transistor are both provided with chromium boride layer on the top surface.

12. The semiconductor device according to claim 11, wherein the gate electrode in the p-type MIS transistor further comprises, between the first metal layer and the chromium boride layer, a barrier layer formed of a material selected from the group consisting of TaSiN, TaN, TiN and TiSiN.

13. A method of manufacturing a semiconductor device, comprising:
forming an insulating film on a semiconductor substrate having a p-type impurity region and an n-type impurity region which are isolated from each other;
forming a metal layer on the insulating film;
forming a boron source film selectively on the metal layer located in the p-type impurity region;
heat-treating the semiconductor substrate having the boron source film to change all the metal layer to metal boride film thereof to selectively form a metal boride film in the p-type impurity region;
forming a gate electrode of an n-type MIS transistor in the p-type impurity region by selectively removing the metal boride film;
forming a gate electrode of a p-type MIS transistor in the n-type impurity region by selectively removing the metal film; and
forming sidewall insulating films on a sidewall of gate electrode of the n-type MIS transistor and a sidewall of gate electrode of the p-type MIS transistor.

14. The method according to claim 14, further comprising injecting an impurity into the semiconductor substrate by using the gate electrode as a mask prior to forming the sidewall insulating film on a sidewall of the gate electrode, thereby forming a heavily doped impurity region.

15. A method of manufacturing a semiconductor device, comprising:
forming an insulating film on a semiconductor substrate having a p-type impurity region and an n-type impurity region which are isolated from each other;
forming a metal boride layer on the insulating film;
forming a boron absorption film selectively on the metal boride film located in the n-type impurity region;
heat-treating the semiconductor substrate having the boron absorption film formed thereon to diffuse boron from the metal boride film in the n-type impurity region to selectively form a metal layer contacted with the insulating film;
forming a gate electrode of an n-type MIS transistor in the p-type impurity region by selectively removing the metal boride film;
forming a gate electrode of a p-type MIS transistor in the n-type impurity region by selectively removing the metal film; and
forming sidewall insulating films on a sidewall of gate electrode of the n-type MIS transistor and a sidewall of gate electrode of the p-type MIS transistor.

16. The method according to claim 15, further comprising injecting an impurity into the semiconductor substrate by using the gate electrode as a mask prior to forming the sidewall insulating film on a sidewall of the gate electrode, thereby forming a heavily doped impurity region.

17. A method of manufacturing a semiconductor device, comprising:
forming an insulating film on a semiconductor substrate having a p-type impurity region and an n-type impurity region which are isolated from each other;
forming a metal layer on the insulating film;
ion-implanting boron selectively into the metal layer located in the p-type impurity region to form a metal boride film;
forming a gate electrode of an n-type MIS transistor in the p-type impurity region by selectively removing the metal boride film;
forming a gate electrode of a p-type MIS transistor in the n-type impurity region by selectively removing the metal film; and
forming sidewall insulating films on a sidewall of gate electrode of the n-type MIS transistor and a sidewall of gate electrode of the p-type MIS transistor.

18. The method according to claim 17, further comprising injecting an impurity into the semiconductor substrate by using the gate electrode as a mask prior to forming the sidewall insulating film on a sidewall of the gate electrode, thereby forming a heavily doped impurity region.

19. A method of manufacturing a semiconductor device, comprising:
forming an insulating film on a semiconductor substrate having a p-type impurity region and an n-type impurity region which are isolated from each other;
selectively forming a boron layer through adsorption of boron on the insulating film which is located in the p-type impurity region;
forming a metal layer on the boron film and on the insulating film;
heat-treating the semiconductor substrate having the metal layer formed thereon to diffuse boron from the boron film into the metal layer to selectively form a metal boride film in the p-type impurity region, the metal boride film being contacted with the insulating film;
forming a gate electrode of an n-type MIS transistor in the p-type impurity region by selectively removing the metal boride film;
forming a gate electrode of a p-type MIS transistor in the n-type impurity region by selectively removing the metal film; and
forming sidewall insulating films on a sidewall of gate electrode of the n-type MIS transistor and a sidewall of gate electrode of the p-type MIS transistor.

20. The method according to claim 19, further comprising injecting an impurity into the semiconductor substrate by using the gate electrode as a mask prior to forming the sidewall insulating film on a sidewall of the gate electrode, thereby forming a heavily doped impurity region.
